(19) United States
(12) Patent Application Publication
(10) Pub. No.: US 2025/0006660 A1
(43) Pub. Date: Jan. 2, 2025

(54) METAL FILLING AND TOP METAL SPACING FOR DIE CRACK MITIGATION

(71) Applicant: Texas Instruments Incorporated, Dallas, TX (US)

(72) Inventors: Yutaka Suzuki, Allen, TX (US); Clinton E. Granger, III, Bellville, TX (US); Jaimal Williamson, Dallas, TX (US); Rajen Murugan, Dallas, TX (US)

(21) Appl. No.: 18/343,824

(22) Filed: Jun. 29, 2023

(51) Int. Cl. H01L 23/00; H01L 21/768; H01L 23/31; H01L 23/522

(52) U.S. Cl. CPC H01L 23/562; H01L 21/768; H01L 23/3121; H01L 23/5226; H01L 24/11; H01L 24/16; H01L 2224/11; H01L 2224/16227

(57) ABSTRACT

An electronic device includes a semiconductor die having a semiconductor body, a metallization structure over the semiconductor body and a conductive terminal, the metallization structure including a top level having neighboring first and second top metal structures that extend in a plane of orthogonal first and second directions, the first top metal structure is electrically coupled to the conductive terminal, the conductive terminal extends over a portion of the first top metal structure and away from the plane along a third direction orthogonal to the first and second directions, and the first top metal structure is spaced apart from the second top metal structure in the plane by a spacing distance of 60 μm or more.

### BACKGROUND

Multilevel metallization structures of a semiconductor die have multiple levels with metal and interlevel or interlayer dielectric (ILD) layers in a stacked arrangement for signal and power routing and interconnections. However, performance degradation and possible device failure can result from interfacial delamination and ILD cracking due to poor fracture strength and brittle mechanical behavior for ILD layers.

### SUMMARY

In one aspect, an electronic device includes a semiconductor die having a semiconductor body, a metallization structure over the semiconductor body, and a conductive terminal. The metallization structure includes a top level having neighboring first and second top metal structures that extend in a plane of orthogonal first and second directions, with the first top metal structure electrically coupled to the conductive terminal and the conductive terminal extending over a portion of the first top metal structure and away from the plane along an orthogonal third direction. The first top metal structure is spaced apart from the second top metal structure in the plane by a spacing distance of 60 μm or more.

In another aspect, an electronic device includes a semiconductor die having a semiconductor body, a metallization structure over the semiconductor body, and a conductive terminal, where the metallization structure includes a top level a top metal structure that extends in a plane of orthogonal first and second directions and the top metal structure is electrically coupled to the conductive terminal, The conductive terminal extends over a portion of the top metal structure and away from the plane along an orthogonal third direction and the top metal structure overlaps all lateral edges of the conductive terminal by a non-zero overlap distance.

In a further aspect, a system includes a circuit board and an electronic device having a semiconductor die. The semiconductor die has a semiconductor body, a metallization structure over the semiconductor body, and a conductive terminal. The metallization structure includes a top level having neighboring first and second top metal structures that extend in a plane of orthogonal first and second directions, with the first top metal structure electrically coupled to the conductive terminal and the conductive terminal extending over a portion of the first top metal structure and away from the plane along an orthogonal third direction. The first top metal structure is spaced apart from the second top metal structure in the plane by a spacing distance of 60 μm or more.

In another aspect, a method of fabricating an electronic device includes forming a metallization structure over a semiconductor body, including forming a top level having neighboring first and second top metal structures in a plane of orthogonal first and second directions, the first top metal structure spaced apart from the second top metal structure in the plane by a spacing distance of 60 μm or more, as well as forming a protective overcoat layer over the metallization structure, and forming a conductive terminal electrically coupled to the conductive terminal and extending through the protective overcoat layer over a portion of the first top metal structure and away from the plane along a third direction that is orthogonal to the first and second directions.

### BRIEF DESCRIPTION OF THE DRAWINGS

FIGS. 1 and 1A are sectional side elevation views of a packaged electronic device with a semiconductor die having a top metal layer with top metal structures laterally overlapping conductive terminals along with top metal structure spacing to mitigate ILD cracking.

FIG. 1B is a partial top plan view of the metallization structure of the semiconductor die.

FIGS. 1C and 1D includes graphs of stress modeling data.

FIGS. 2 and 2A are sectional side elevation views of another example packaged electronic device with a semiconductor die having a top metal layer with top metal structures laterally overlapping conductive terminals to mitigate ILD cracking.

FIG. 3 is a flow diagram showing a method of fabricating an electronic device.

FIGS. 4-14 are partial sectional side elevation views showing the electronic device of FIGS. 1-1B undergoing fabrication processing according to the method of FIG. 3.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value.

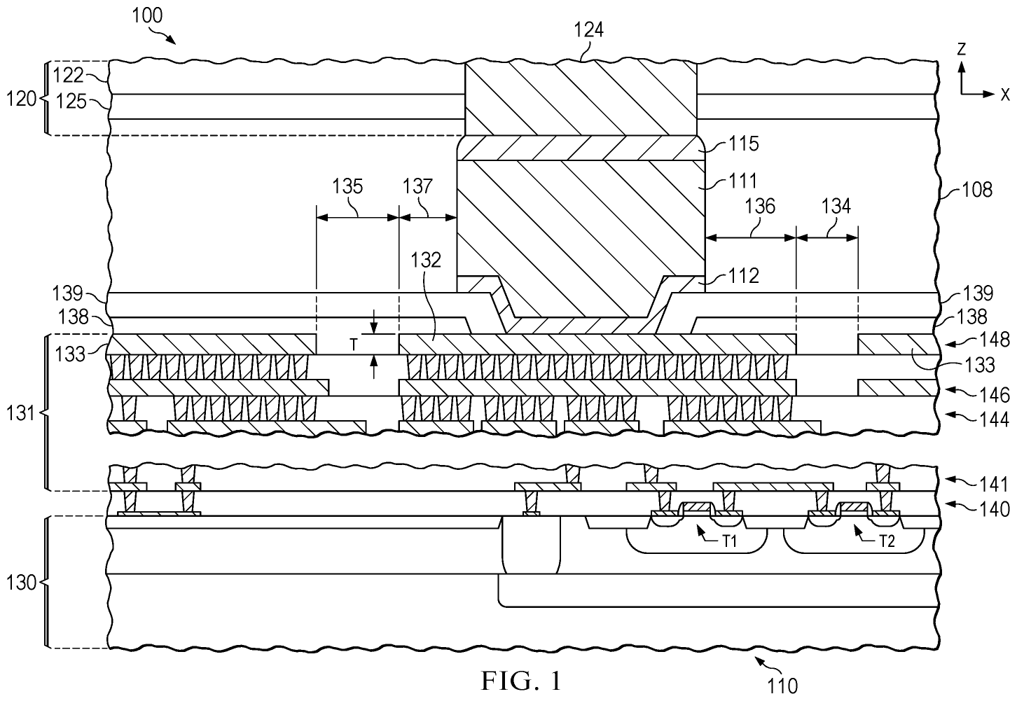

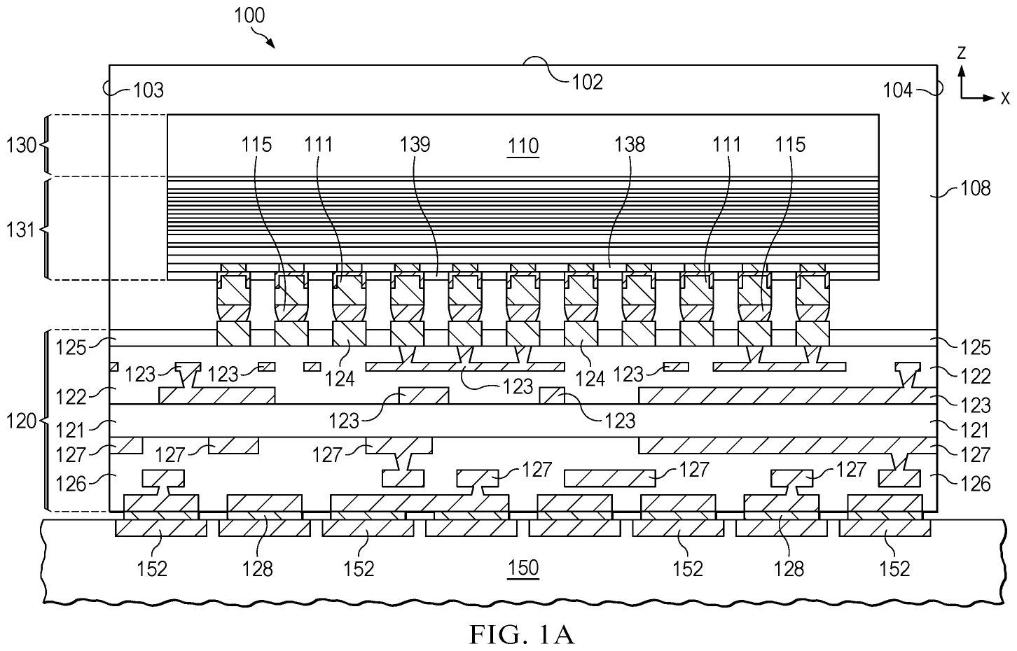

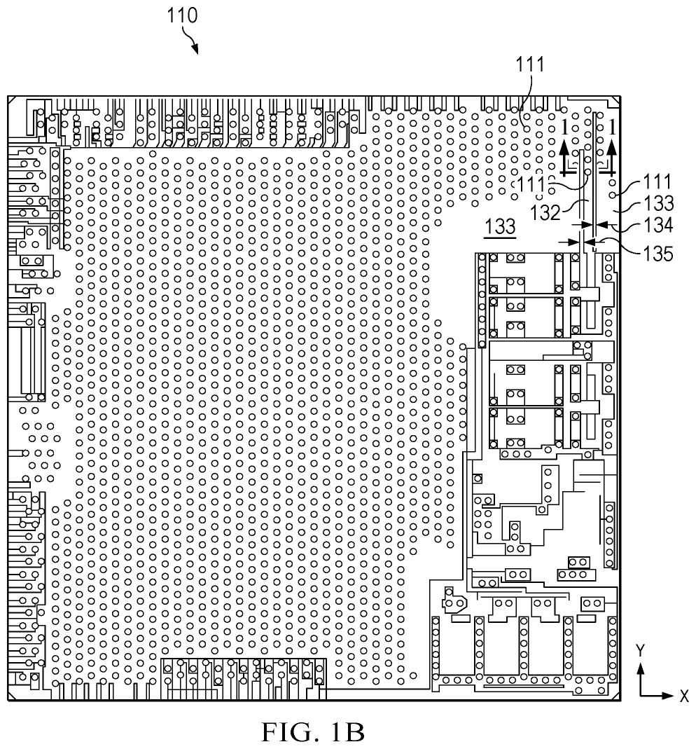

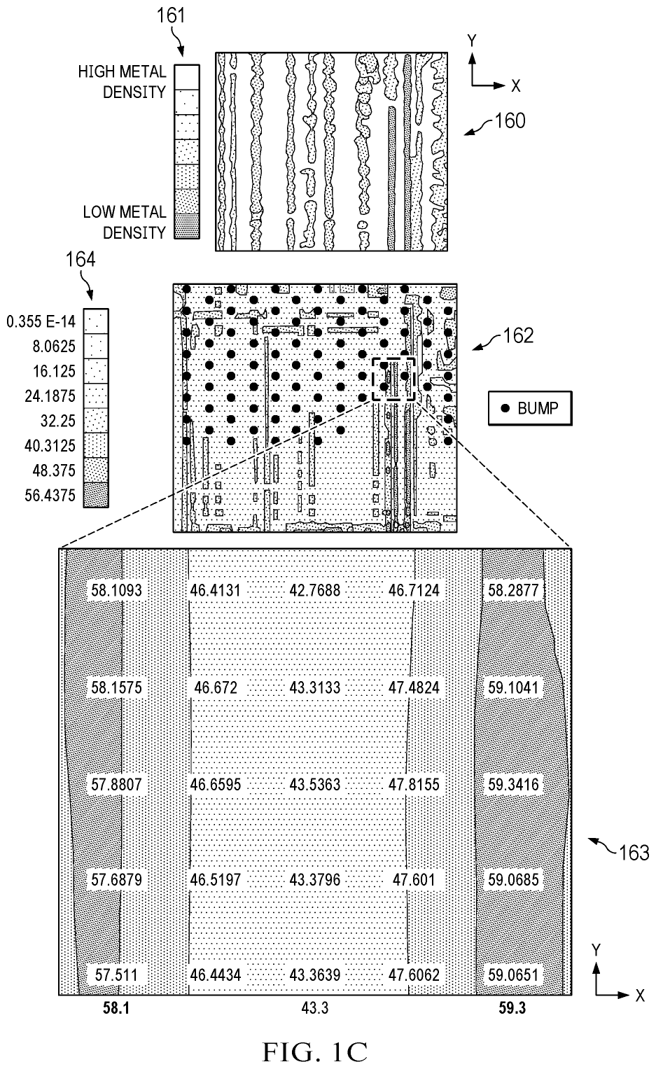

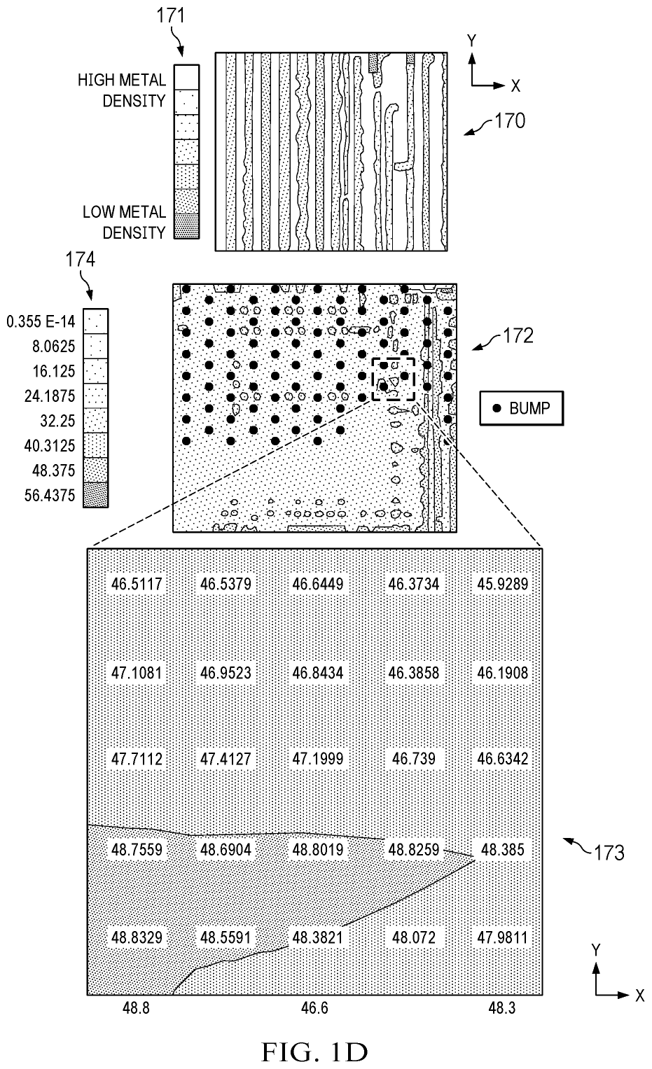

FIGS. 1-1B show a packaged electronic device 100 with a semiconductor die 110 having a multilevel metallization structure 131 including a top metal layer with top metal structures 132 laterally overlapping conductive terminals 111 along with top metal structure spacing to mitigate ILD cracking. The illustrated electronic device 100 is a flip-chip chip scale package (FCCSP) device. Other device package forms and types can be used in other implementations, such as having leads formed from a starting lead frame and internal bond wire connections, flip chip ball grid array (FCBGA) devices, etc. The top metal feature design mitigates ILD cracking and interfacial delamination, including the illustrated flip chip configuration, and can be used even in complex metallization layer stacking arrangements that induce stress accumulation around metal bump or pillar interconnection due to thermal stress between the semiconductor die and a package substrate. High metal density transitions or gradients in certain metallization structure designs can generate larger stress due to thermal expansion mismatch and edge impact between metal and ILD materials, and stress around bump interconnection can increase the risk of ILD cracking.

The electronic device 100 mitigates or avoids high metal density gradients through top metal filling to overlap copper pillars or bumps or other conductive terminals, and by controlled spacing of top metal structures. High stress can be generated at a boundary between high and low metal density areas in a metallization structure (e.g., high metal density gradient regions). Sharp high/low metal density transitions can increase stress in ILD materials due to thermal expansion mismatch and edge impact between metal and ILD. In addition, higher stress can occur around bump interconnections and increase the risk of ILD cracking and/or delamination. Finite element modeling indicates regions of high stress singularity at the boundary between high/low metal density transitions. Selectively filling top metal structures to laterally overlap the sides of conductive terminals (e.g., copper pillars, bumps, etc.) to compensate for the sharp metal transition regions can help reduce the risk of ILD cracking. Further, or in combination, increasing the lateral spacing between neighboring top metal structures can reduce ILD stress levels and crack risks.

FIG. 1A shows the electronic device 100 installed in a system, such as a smart phone, laptop or desktop computer, a tablet, an automotive system, an industrial system, etc. The electronic device 100 is shown in an example position or orientation in a three-dimensional space with a first direction X, a perpendicular (orthogonal) second direction Y (into the page, not numerically designated in FIGS. 1 and 1A), and a third direction Z that is perpendicular (orthogonal) to the respective first and second directions X and Y. Structures or features along any two of these directions are orthogonal to one another. As shown in FIG. 1A, the electronic device 100 has a first (e.g., bottom) side and an opposite second (e.g., top) side 102, which are spaced apart from one another along the third direction Z, as well as laterally opposite third and fourth sides 103 and 104 that are spaced apart from one another along the first direction X and opposite fifth and sixth sides (not shown) that are spaced apart from one another along the second direction Y. The sides in one example have substantially planar outer surfaces. In other examples (not shown), one or more of the sides of the electronic device 100 have curves, angled features, or other non-planar surface features. The electronic device 100 has a package structure 108 (FIGS. 1 and 1A), such as a molded plastic structure that forms all or a portion of the second side and upper portions of the lateral sides.

The semiconductor die 110 is partially enclosed by the package structure 108 and the die 110 is flip chip attached (e.g., by solder connections) to a multilevel package substrate 120. The molded package structure 108 extends onto and encloses portion of a top side of the multilevel package substrate 120. The semiconductor die 110 has generally planar top and bottom sides and conductive terminals 111 along the bottom side. The semiconductor die 110 includes one or more electrical circuit components (e.g., transistors T1 and T2 in FIG. 1) as well as conductive terminals 111 (FIGS. 1 and 1A). At least some of the conductive terminals 111 provide circuit connections to interconnect other external devices and/or components to a circuit of the electronic device 100. The conductive terminals 111 in the illustrated examples are conductive metal pillars (e.g., copper, etc.) that extend outward from the bottom side of the semiconductor die 110. This facilitates flip-chip die attachment and soldering to form electrical connections to the circuitry of the electronic device 100. The conductive terminals 111 in one example each have a solder cap 115 applied to the ends thereof, for example, by electroplating during a bumping process or other suitable dipping, printing or other process to allow flip-chip attachment and thermal reflow to make electrical and mechanical connections thereto. In one example for flip chip chip scale packages, the terminals 111 are copper pillars formed by electroplating in a bumping process, which is followed by electroplating of the solder portions 115 on top of the copper pillar during the wafer bumping process. For FCBGAs, the flip chip side substrate pad can have solder as well as other finishes like OSP, ENEPIG, etc. The bump interconnect formed on a processed wafer in one example is or includes copper and a solder cap, which is subsequently attached to the package substrate 120 to form electrical interconnections of a circuit of the electronic device 100.

As best shown in FIG. 1A, the illustrated example package substrate 120 is a multilevel package substrate 120. In other implementations, a single level substrate can be used and/or a different type of substrate can be used. The multilevel package substrate 120 includes multiple dielectric layers or levels with patterned conductive features formed thereon and therebetween to provide circuit signal and power routing for the circuitry of the electronic device 100. The illustrated multilevel package substrate 120 has a core (e.g., middle) dielectric layer 121 that may include conductive vias or other conductive structures extending therethrough (not shown), and an upper dielectric level 122 with patterned conductive metal features 123 (e.g., copper or other metal) and upper conductive features 124 facing the semiconductor die 110. Other substrate forms and types can be used in different implementations, including coreless substrates (not shown). The upper dielectric level 122 can have a single dielectric layer, such as compression molded dielectric material, or can include multiple dielectric layers with associated conductive metal interconnection features 123 such as traces, vias, etc. The conductive terminals 111 of the semiconductor die 110 are soldered to respective ones of the conductive features 124 of the package substrate 120 by the respective solder portions 115. The multilevel package substrate 120 in one example also includes a solder mask layer 125 on a top side of the upper dielectric layer 121 with openings to allow electrical and mechanical connection of the respective conductive features 124 to the conductive terminals 111 and associated solder portions 115 of the bottom side of the semiconductor die 110, for example, by flip-chip die attach processing such as placement and subsequent thermal reflow to create solder connections as shown in FIG. 1A. The package substrate 120 also has a lower dielectric level 126 with patterned conductive metal features 127 (e.g., copper or other metal). Certain of the conductive metal features 127 have sides exposed to the bottom side of the electronic device 100 to allow electrical connections to a host circuit board, for example, by solder 128 in the illustrated FCCSP configuration of the electronic device 100. The lower dielectric level 126 can have a single dielectric layer, such as compression molded or laminated dielectric material, or can include multiple dielectric layers with associated conductive metal interconnection features 127 such as traces, vias, etc. as shown in the example of FIG. 1.

The semiconductor die 110 has a semiconductor body 130 (e.g., silicon or other suitable semiconductor material) on and/or in which the transistors T1, T2 and any other circuit components are formed. The metallization structure 131 extends over the semiconductor body 130. As shown in FIG. 1, the metallization structure 131 has a top metal level 148 with top metal features 132 and 133 that extend in a plane of orthogonal the respective first and second directions X and Y, including a first top metal structure 132 and laterally neighboring second top metal structures 133. The first top metal structure 132 and the second top metal structures 133 have a thickness T along the third direction Z. As further shown in the top view of FIG. 1B, the second top metal structures 133 in the illustrated section of FIG. 1 are the nearest top metal structures to the first top metal structure 132. The first top metal structure 132 is electrically coupled to the conductive terminal 111. In the illustrated example, the conductive terminal 111 is electrically connected to a portion of the top side of the first top metal structure 132 by a conductive metal structure 112, referred to as an under bump metal (e.g., copper). The conductive terminal 111 extends over a portion of the first top metal structure 132 and extends upward in the orientation of FIG. 1 away from the plane along the third direction Z. In one implementation, the distance between high and low metal density regions and the spacing between neighboring top metal features is controlled at least partially according to die location in a given packaged electronic device design, for example, the region denoted in the upper right in FIG. 1B with high-low-high metal density transitions proximate a die corner. In general, a good practice would be to implement the controlled top metal feature spacing across the entire die.

The first top metal structure 132 is spaced apart from the right most second top metal structure 133 in the plane by a spacing distance 134, and the first top metal structure 132 is spaced apart from the left most second top metal structure 133 by a spacing distance 135. In order to mitigate ILD layer cracking in the electronic device 100, the first top metal structure 132 is laterally spaced apart from each neighboring top level metal structure 133 by a spacing distance 134, 135 of 60 μm or more. In certain examples, the spacing distances 134, 135 are 80 μm or more. Increasing the lateral spacing distances 134 and 135 between neighboring top metal structures helps reduce ILD stress levels and crack risks in the electronic device 100. FIGS. 1C and 1D show comparative stress modeling data. FIG. 1C shows a model of metal density 160 and a corresponding metal density scale 161 for a portion of a multilevel metallization structure including top metal features laterally spaced along the first direction X by less than 60 μm, along with a corresponding model of ILD stress 162, a zoomed portion 163 and a corresponding scale 164. FIG. 1D shows a model of metal density 170 and a corresponding metal density scale 171 for a portion of the example multilevel metallization structure 131 in the electronic device 100 with top metal features laterally spaced along the first direction X by more than 60 μm, along with a corresponding model of ILD stress 172, a zoomed portion 173 and a corresponding scale 174. The comparative stress models show a significant reduction in ILD stress (e.g., stress model 172 vs. stress model 162) by increased lateral spacing distances 134 and 135 between neighboring top metal structures to reduce ILD stress levels and crack risks in the electronic device 100.

In the illustrated example, moreover, the first top metal structure 132 overlaps all lateral edges of the conductive terminal 111 by a non-zero overlap distance 136, 137. In one example, the overlap distance 136, 137 is greater than the thickness T of the top metal structures. As further shown in FIG. 1, the conductive terminal 111 is soldered to a respective conductive feature 124 of a package substrate 120. The lateral overlapping of the sides of the first top metal structure 132 beyond the lateral sides of the associated conductive terminal 111 helps mitigate high metal density gradients in the ILD materials of the multilevel metallization structure 131.

As shown in FIGS. 1 and 1A, the metallization structure 131 extend from a protective overcoat layer 138 toward the semiconductor body 130 proximate the lateral sides of the semiconductor die 110. The protective overcoat layer 138 extends over the metallization structure 131. In one example, the protective overcoat layer 138 is or includes an inorganic-based passivation material, such as a silicon nitride (SiN), silicon oxynitride (SiOₓN_{y}), or silicon dioxide (SiO₂). An organic-based passivation layer, such as a polyimide 139 extends over the protective overcoat layer 138, and the conductive terminals 111 extend from the metallization structure 131 through the protective overcoat layer 138 and the polyimide layer 139. As shown in FIG. 1A, the flip-chip chip scale package example electronic device 100 is installed on a circuit board 150 in the system of FIG. 1, with respective ones of the substrate leads soldered to provide mechanical and electrical connections to conductive metal board pads 152 of the circuit board 150.

The conductive terminal overlapping and/or controlled minimum lateral spacing of the top metal features 132, 133 can be used in a multilevel metallization structure 130 having any suitable integer number of metallization levels. The illustrated example in FIG. 1 includes a pre-metal dielectric (PMD) layer 140 with conductive metal (e.g., tungsten) contacts extending therethrough along the third direction Z, for example, to form connections to the terminals of the transistors T1 and T2. A first metallization level 141 extends over the PMD layer 140 and includes a dielectric material (ILD) as well as conductive metal features (e.g., traces and vias). The illustrated multilevel metallization structure 131 has further levels, including a level 144 with associated ILD material (e.g., silicon dioxide (SiO₂) and conductive trace and via features, and an overlying further metallization level 146 with corresponding ILD dielectric material, and associated trace and via features. In one implementation, the metallization levels 141, 144, and 146 include conductive copper trace and via features, and the top metal structures 132 and 133 of the top metal level 148 are or include aluminum. In different implementations, different conductive metals can be used.

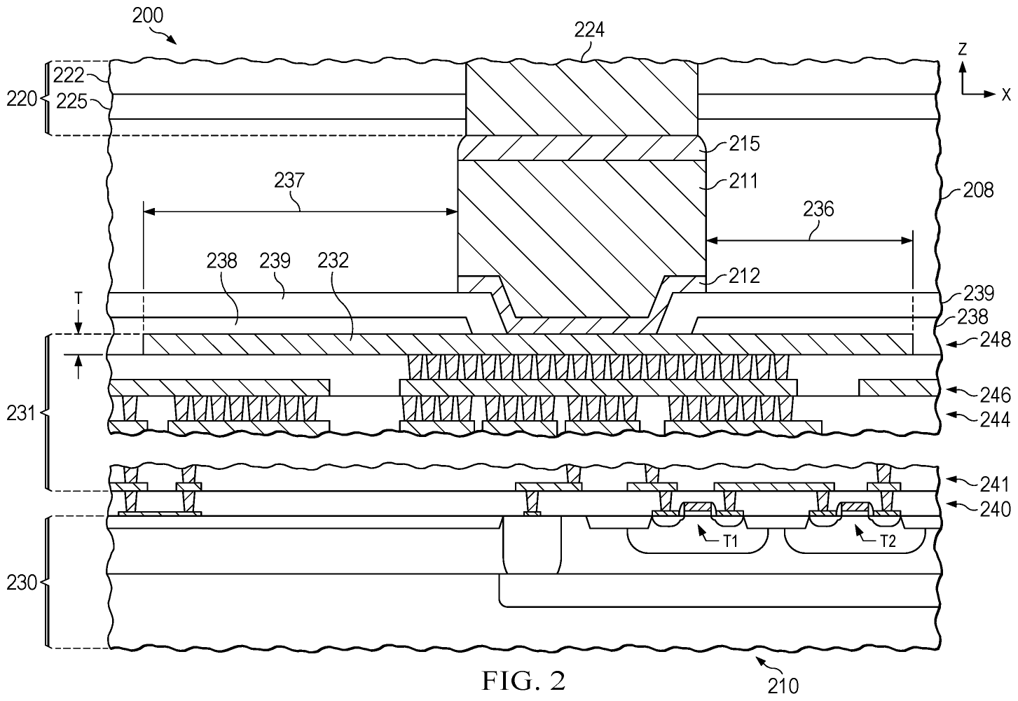

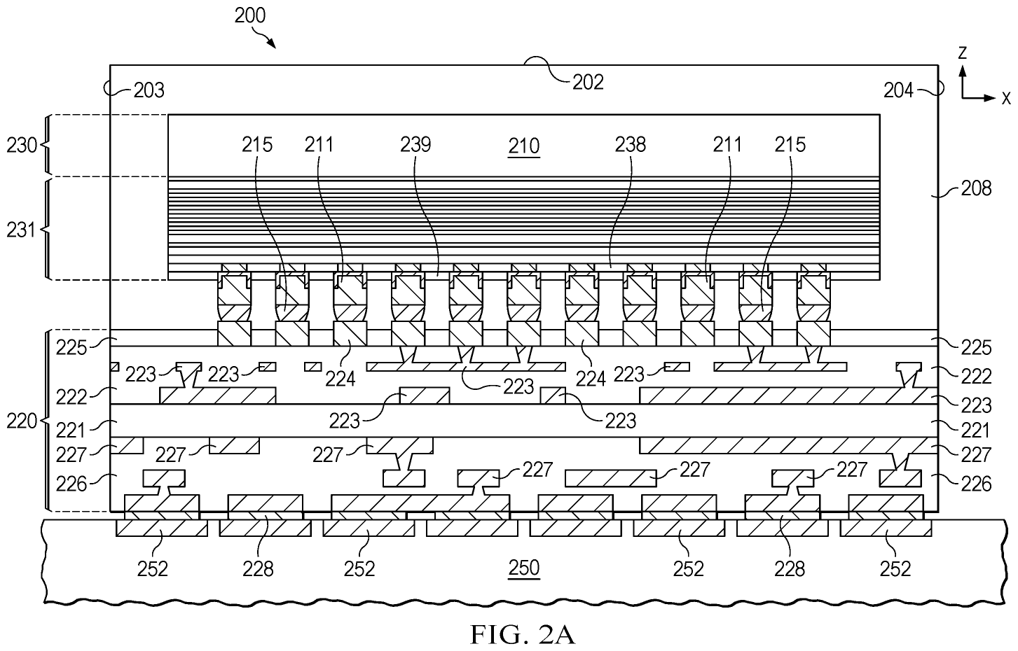

FIGS. 2 and 2A show another example packaged electronic device 200 with a semiconductor die 210 having a top metal layer 248 with top metal structures 232 laterally overlapping conductive terminals 211 to mitigate ILD cracking, where FIG. 2A shows the electronic device 200 installed on a circuit board 250 of a system. The electronic device 200 and the system have components, features, dimensions and structures 202-204, 208, 210-212, 215, 220-228, 230-232, T. T1, T2, 236-241, 244, 246, 248, 250 and 252 that generally correspond with the respective features and structures 102-104, 108, 110-112, 115, 120-228, 130-132, T. T1, T2, 136-141, 144, 146, 148, 150 and 152 described above in connection with the electronic device examples 100 of FIGS. 1-1B unless otherwise indicated. The electronic device 200 in this example provides overlapping of the top metal conductive structure 232 extending laterally beyond the lateral edge or edges of the conductive terminal 211 by a non-zero overlap distance 236, 237. In one example, the overlap distance 236, 237 is greater than the thickness T of the top metal structure 232 of the multilevel metallization structure 231. As further shown in FIG. 1, the conductive terminal 111 is soldered to a respective conductive feature 124 of a package substrate 120. The lateral overlapping of the sides of the first top metal structure 132 beyond the lateral sides of the associated conductive terminal 111 helps mitigate high metal density gradients in the ILD materials of the multilevel metallization structure 231.

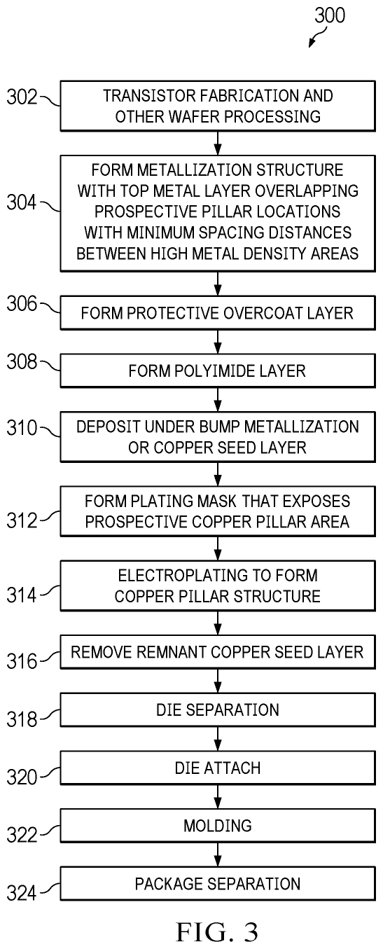

Referring to FIGS. 3-14, FIG. 3 shows a method 300 of fabricating an electronic device and FIGS. 3-14 show the electronic device 100 of FIG. 1 undergoing fabrication processing according to an example implementation of the method 300. The example method 300 includes wafer processing with transistor and other component fabrication on or in a semiconductor body using a starting semiconductor wafer at 302, for example, to form the transistors T1 and T2 and other circuit components of the semiconductor body 130 for the finished electronic device 100 described above.

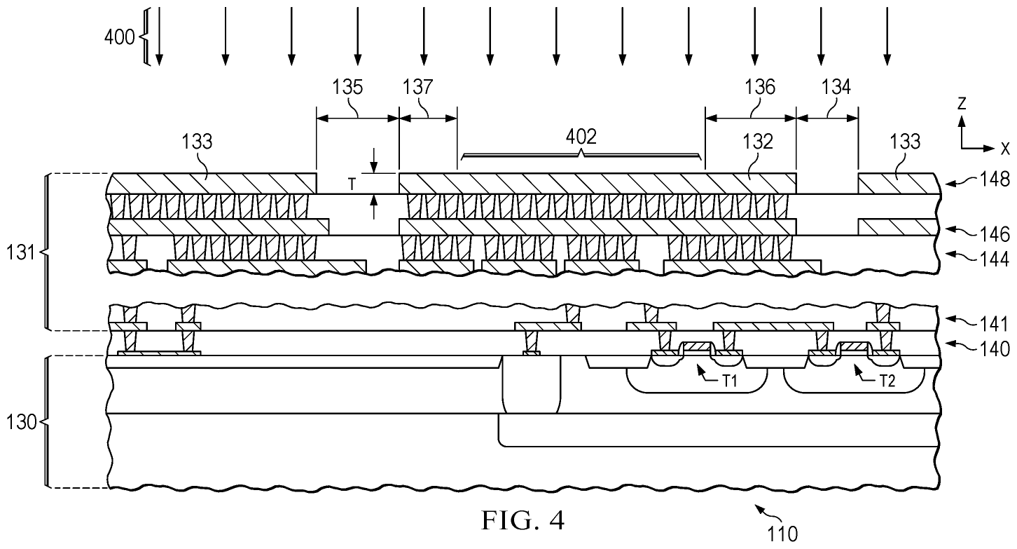

At 304 in FIG. 3, the method 300 includes forming a single or multilevel metallization structure over the semiconductor body. In one example, the metallization processing at 304 includes forming the top level 148 to the thickness T along the third direction Z and having the neighboring first and second top metal structures 132, 133 in an X-Y plane with the first top metal structure 132 spaced apart from the second top metal structure 133 in the plane by the spacing distance 134, 135 of 60 μm or more, such as 80 μm or more. In one implementation, moreover, the first top metal structure 132 is formed and overlaps (i.e., outwardly extends past) the lateral edges of all lateral edges of a prospective conductive terminal 111 by the non-zero overlap distance 136, 137, such as greater than the thickness T of the top metal structures 132, 133. In one implementation, the top metal structures 132, 133 are or include aluminum. In another implementation, the top metal structures 132, 133 can be a different metal (e.g., copper, etc.). FIG. 4 shows one example, in which a metallization fabrication process 400 is performed on a processed wafer having rows and columns of unit areas corresponding to prospective semiconductor dies 110. FIG. 4 shows a prospective conductive contact location or area 402 in which a conductive copper pillar, bump, etc., will subsequently be formed. The process 400 forms the multilevel metallization structure 131 above the semiconductor body 130, for example, directly on or over the semiconductor body 130. The metallization process 400 also includes forming other electrical interconnection structures (not shown in the drawings) to interconnect transistors and/or other components of one or more circuits of the prospective semiconductor die 110, for example, using single and/or dual damascene processing steps (not shown) to form one or more levels having dielectric material(s) and conductive structures such as traces, inter level vias, etc.

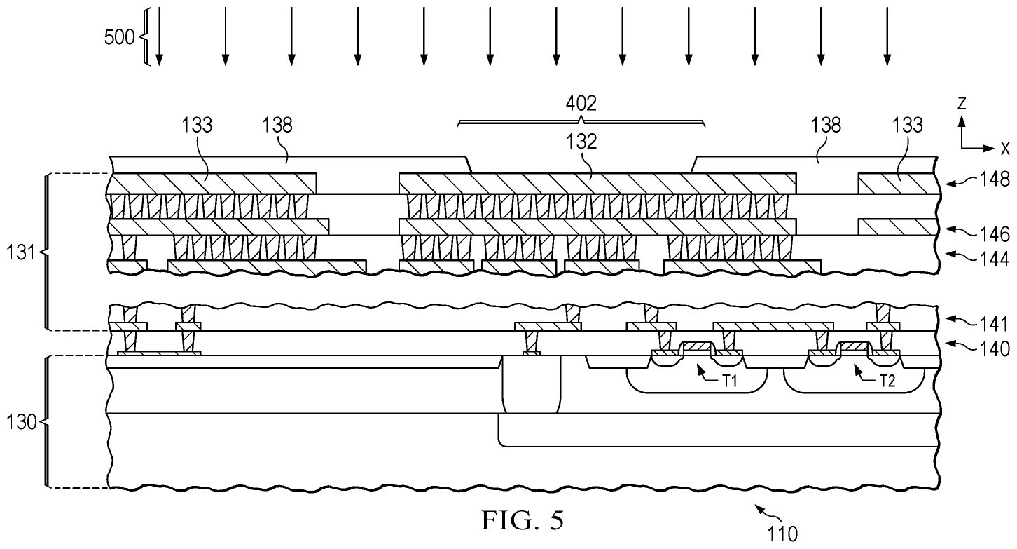

The method 300 continues at 306 in FIG. 3 with protective overcoat layer formation. FIG. 5 shows one example, in which a deposition process 500 is performed that forms the protective overcoat layer 138 over (e.g., directly on or otherwise above) the metallization structure 131 (e.g., directly on or otherwise above) portions of the top metal structures 132 and 133 and exposing a portion of the first top metal structure 132 in the prospective conductive contact location or area 402. In one example, the process 500 forms the protective overcoat layer 138 at 306 to any suitable thickness that is or includes an inorganic-based passivation material, such as a silicon nitride, silicon oxynitride, silicon dioxide, etc.

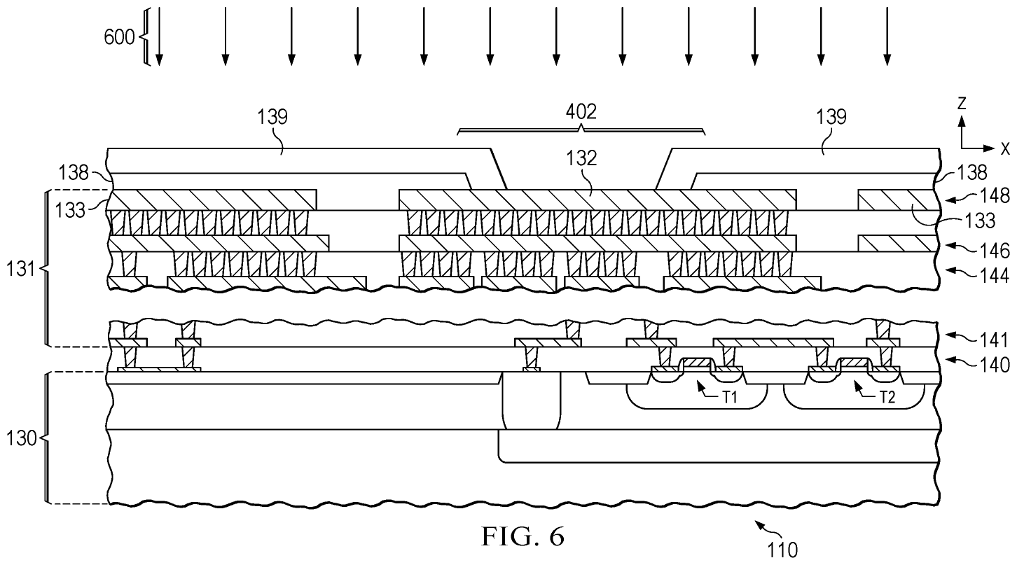

At 308 in FIG. 3, the method 300 continues in one example with forming an organic passivation layer 139 with an opening in the prospective conductive contact area 402. FIG. 6 shows one example, in which a deposition process 600 is performed that forms the polyimide layer 139 on select portions of the protective overcoat layer 138 in between the prospective conductive terminal areas and the prospective protruded metal feature locations.

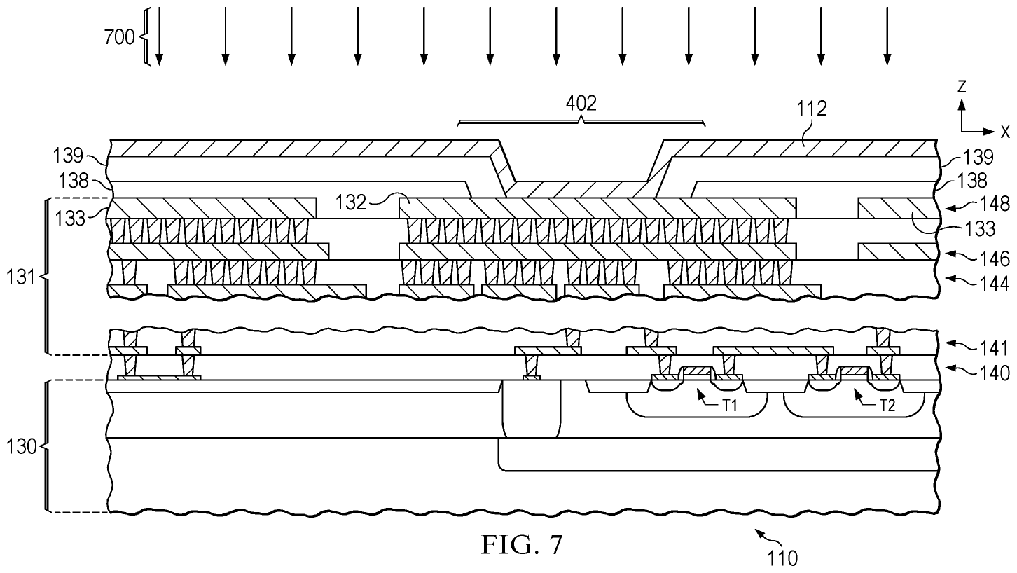

The method 300 continues at 310-314 to form the conductive terminal 111 electrically coupled to the first top metal feature 132 and extending through the protective overcoat layer 138 over a portion of the first top metal structure 132 and away from the top metal X-Y plane along the third direction Z. One implementation begins at 310 with forming an under bump metal at least partially above the top metal feature 132, for example, by printing or other selective deposition process (not shown). At 310 in this example, a copper seed layer is deposited over the exposed portions of the first top metal structure 132 and the protective overcoat layer 138 and over the top side of the polyimide layer 139. In this example, a deposition process 700 is performed in FIG. 7, such as a chemical vapor deposition (CVD) process, which forms the under bump metal layer 112 as a copper seed layer over the protective overcoat layer 138, the polyimide layer 139, and over the exposed portion of the first top metal structure 132. The copper seed layer 112 is formed to any suitable thickness, for example, that facilitates subsequent selective electroplating of further copper material thereon. In another example, the layer 112 can be a stack of two or more conductive metal layers, sometimes referred to as under bump metallurgy (UBM) in a bumping process.

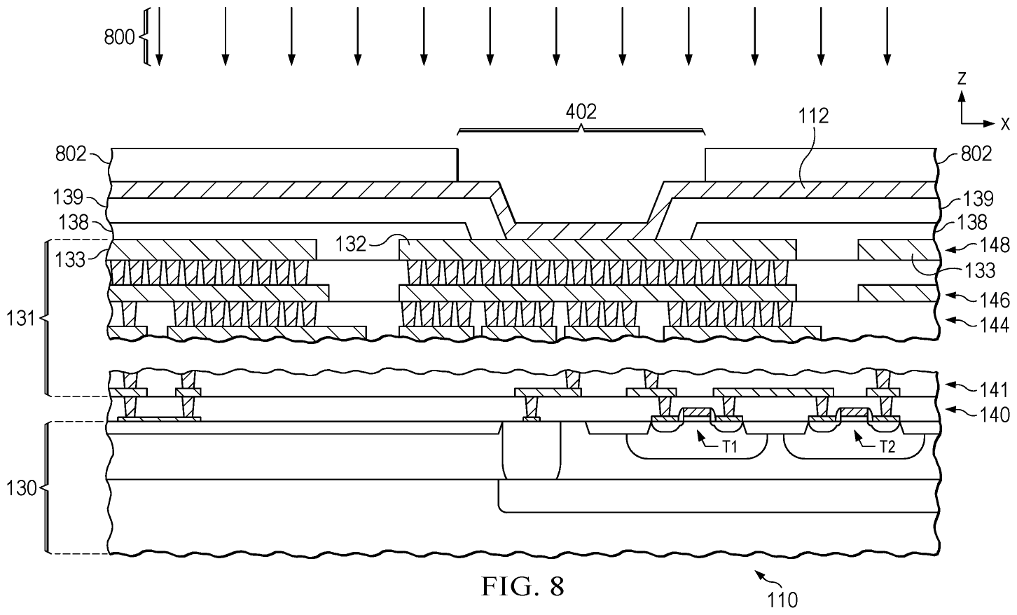

At 312 in FIG. 3, the example implementation further includes forming a first plating mask that exposes portions of the copper seed layer. FIG. 8 shows one example, a process 800 is performed, in which a first plating mask 802 is formed (e.g., deposited, selectively exposed, and patterned) that exposes an area over the under bump metal layer 112 in the prospective conductive contact area 402 (e.g., corresponding to the subsequently formed conductive contact 111 in the example of FIG. 1 above). In the illustrated example, the under bump metal copper seed layer 112 is used as a base for electroplating the conductive terminals 111 in each unit area corresponding to a prospective semiconductor die 110.

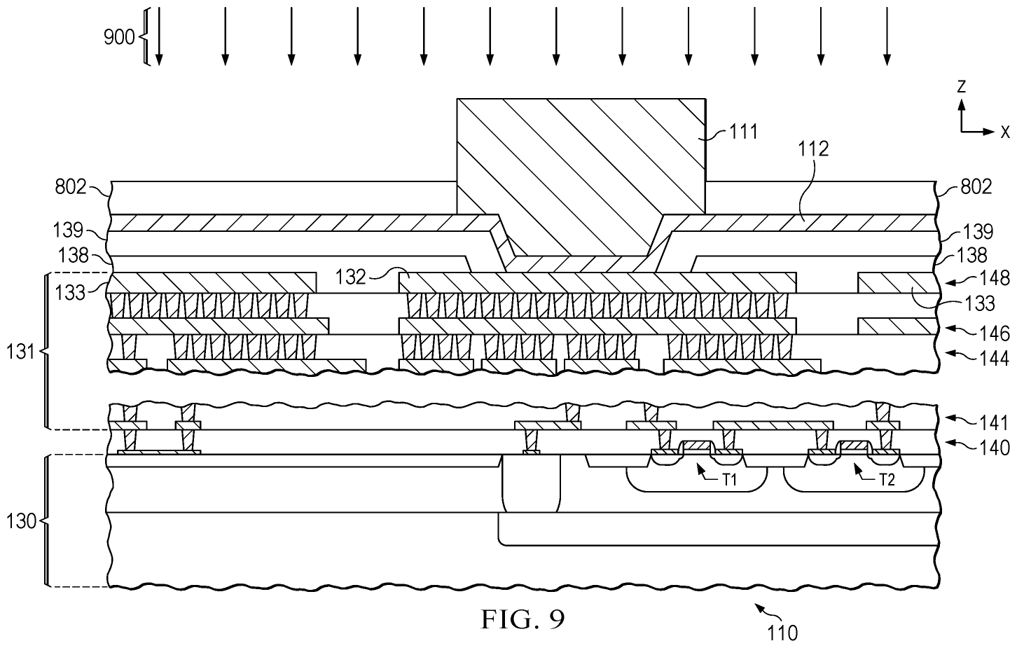

At 314 in FIG. 3, the method 300 continues with electroplating to form the conductive contact 111. FIG. 9 shows one example, in which an electroplating process 900 is performed that deposits copper to form the conductive contact 111 in the openings of the first plating mask 802 to any suitable thickness.

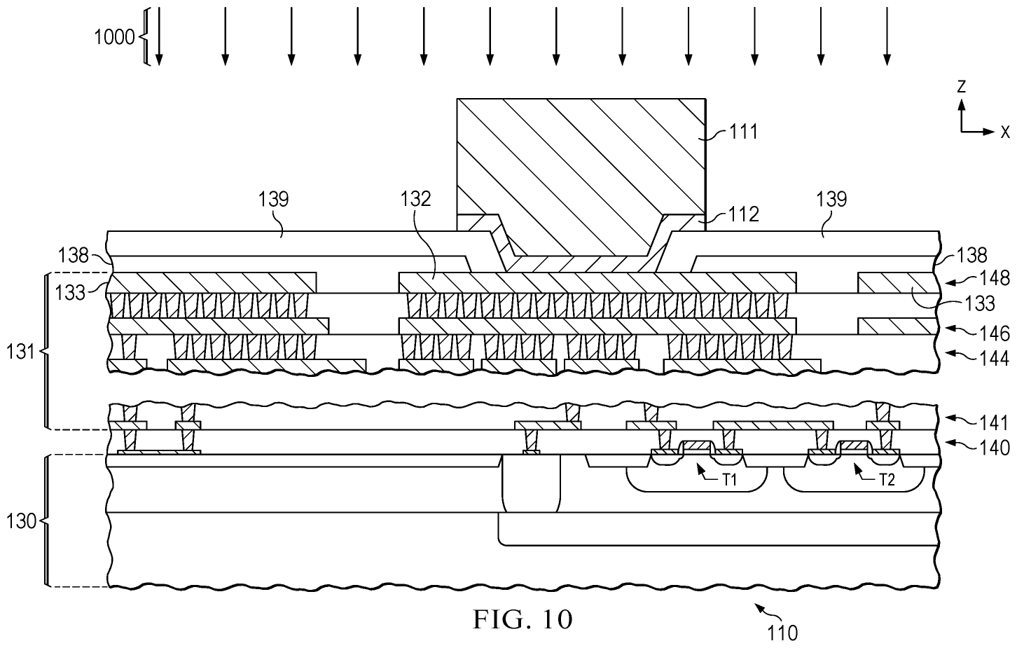

At 316, the remaining exposed portions of the second copper seed layer are removed laterally outward of the plated conductive contact 111. FIG. 10 shows one example, in which an etching or other process 1000 is performed that removes the copper seed layer between the respective conductive terminals 111. The process 1000 may remove a small amount of the plated conductive contacts 111 and the initial electroplating thicknesses can be increased by a suitable amount such that the finished conductive contact 111 has the desired final thickness after the process 1000 is finished.

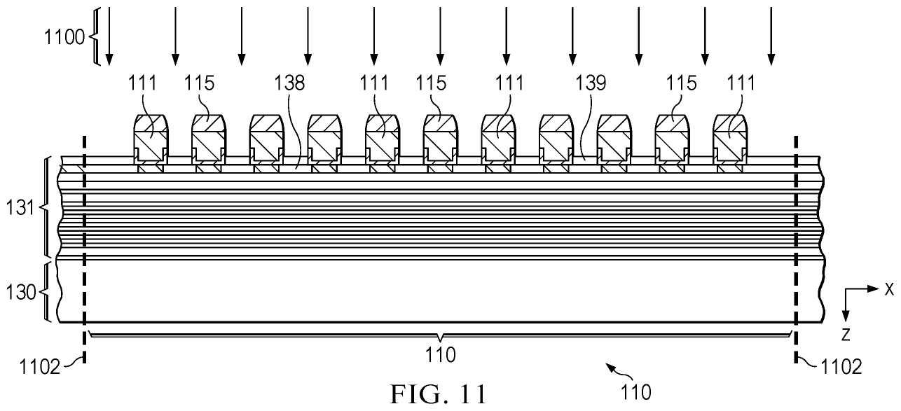

At 318 in FIG. 3, the method 300 continues with die singulation or separation processing. FIG. 11 shows one example, in which a cutting process 1100 is performed that cuts along lines 1102 in scribe streets or scribe areas between adjacent unit areas of the processed wafer in order to separate individual semiconductor dies 110 from the wafer structure. Any suitable separation or cutting process 1100 can be used at 318, such as saw cutting, laser cutting, etching, or combinations thereof, etc.

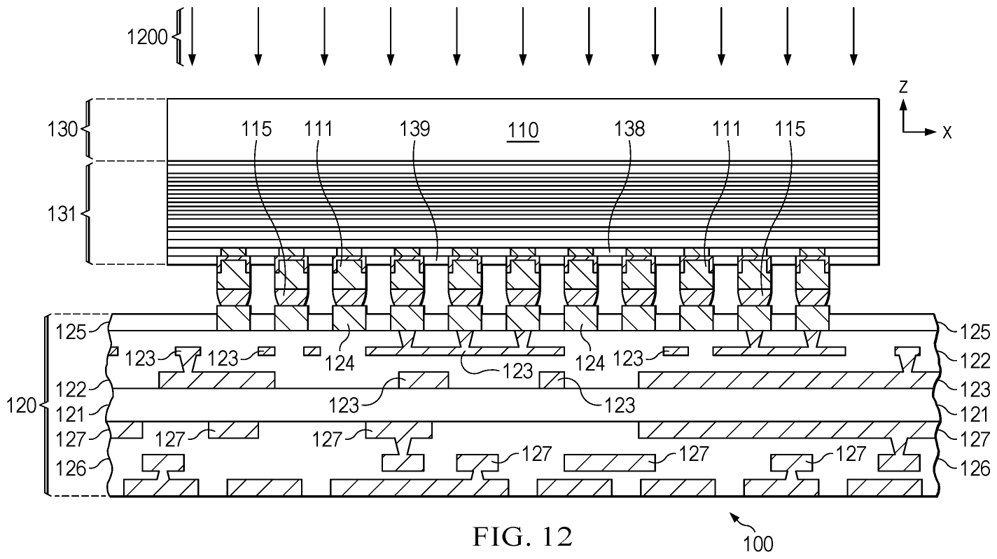

The method 300 continues with die attachment at 320 in FIG. 3. In one example, a lead frame or multilevel package substrate panel array is provided having rows and columns of unit areas, and individual ones of the separated semiconductor dies 110 are attached by flip chip soldering to the corresponding upper conductive features 124 of the substrate. In the illustrated example, a multilevel package substrate structure is provided having rows and columns of individual unit areas for flip-chip die attach processing at 320. FIG. 12 shows one example, in which a flip-chip die attach process 1200 is performed using an array panel with unit areas corresponding to prospective multilevel package substrates 120 as described above in connection with FIGS. 1 and 1A. The die attach process 1200 in one example includes dipping or otherwise providing the solder portions 115 on the ends of the conductive terminals 111 of individual semiconductor dies 110, and subsequent engagement of the solder portions 115 with respective ones of the conductive features 124 of the package substrate 120 in each unit area of the panel array, for example, using automated pick and place equipment (not shown). The die attach process 1200 in one example further includes thermal processing to reflow the solder portions 115 and create solder joints between the individual conductive terminals 111 of the semiconductor die 110 and respective ones of the conductive features 124.

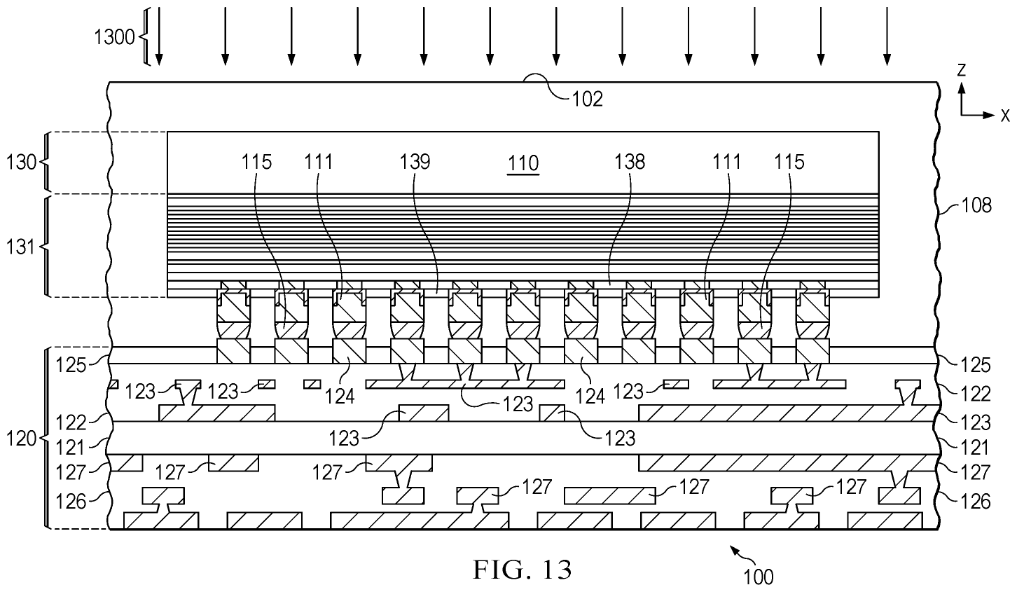

The method 300 continues at 322 in FIG. 3 with package structure formation. In one example, the processing at 322 includes molding operations to form the molded package structure 108 in individual unit areas or groups thereof in the panel array structure. FIG. 13 shows one example, in which a molding process 1300 is performed that forms the package structure 108. In one implementation, the molding at 322 can be performed using any suitable molding equipment. In one implementation, a single mold cavity can be used for an entire panel array or multiple cavities can be used for individual unit areas thereof or groups of unit areas, such as column-wise mold cavities, or combinations thereof. The package structure 108 in one example at least partially encloses the semiconductor die 110 and upper portions of the substrate 120 in each unit area of the panel array. In certain examples, the molding processing at 322 in FIG. 3 can include separate formation of multiple molded portions of a package structure, such as initial mold underfill formation, followed by a subsequent top molding process, or the molding at 322 creates a mold underfill followed by attachment of a metal lid (not shown) over at least a portion of a top side of the semiconductor die 110 without forming a second top mold structure.

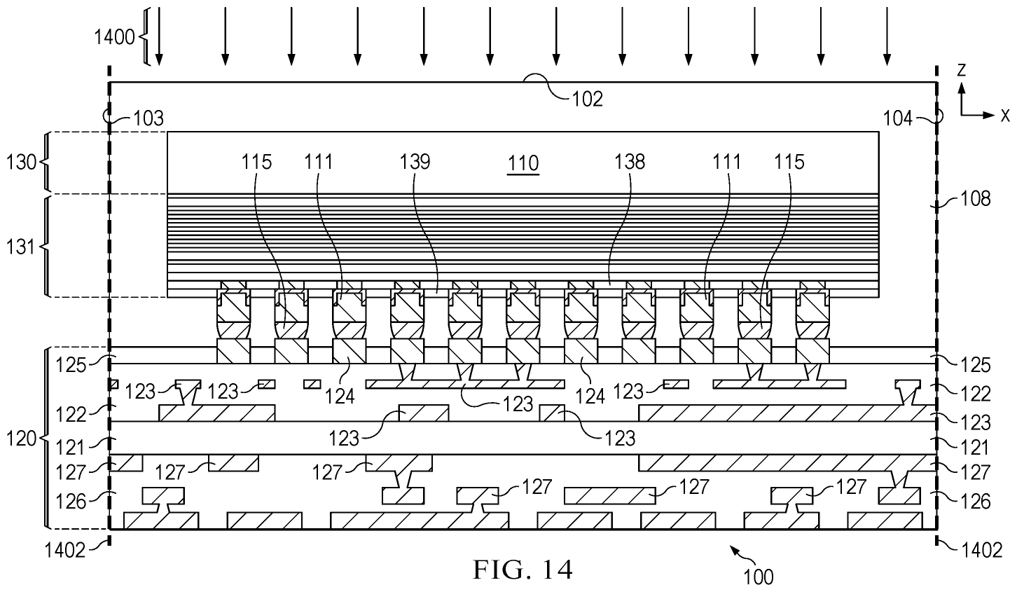

The method 300 in one example also includes package separation at 324 in FIG. 3 to separate individual packaged electronic devices 100 from the processed panel array structure, for example, to form strip or panel array based flip-chip chip scale package (FCCSP) devices (not shown). FIG. 14 shows one example, in which a saw cutting separation process 1400 is performed that separates individual packaged electronic devices 100 from the processed panel array structure by cutting along lines 1402. Any suitable cutting or separation process can be used, including without limitation saw cutting, laser cutting, chemical etching, etc. or combinations thereof. In certain examples, the method 300 can also include final device testing after package separation at 324 and/or wafer level testing (e.g., before die separation at 318 in FIG. 3). In certain implementations, the package separation processing at 324 can be omitted, for example, to form certain flip-chip ball grid array (FCBGA) devices.

Modifications are possible in the described examples, and other implementations are possible, within the scope of the claims.

What is claimed is:

1. An electronic device, comprising:
a semiconductor die having: a semiconductor body; a metallization structure over the semiconductor body; and a conductive terminal, the metallization structure including a top level having neighboring first and second top metal structures that extend in a plane of orthogonal first and second directions, the first top metal structure electrically coupled to the conductive terminal, the conductive terminal extending over a portion of the first top metal structure and away from the plane along a third direction that is orthogonal to the first and second directions, and the first top metal structure spaced apart from the second top metal structure in the plane by a spacing distance of 60 μm or more; and
a package structure that at least partially encloses the semiconductor die.

2. The electronic device of claim 1, wherein the second top metal structure is the nearest top metal structure to the first top metal structure in the top level of the metallization structure.

3. The electronic device of claim 1, wherein the spacing distance is 80 μm or more.

4. The electronic device of claim 3, wherein:
the first top metal structure overlaps all lateral edges of the conductive terminal by a non-zero overlap distance.

5. The electronic device of claim 4, wherein:
the first top metal structure has a thickness along the third direction; and
the overlap distance is greater than the thickness.

6. The electronic device of claim 1, wherein:
the first top metal structure overlaps all lateral edges of the conductive terminal by a non-zero overlap distance.

7. The electronic device of claim 6, wherein:
the first top metal structure has a thickness along the third direction; and
the overlap distance is greater than the thickness.

8. The electronic device of claim 1, wherein:
the conductive terminal is soldered to a conductive feature of a package substrate; and
the package structure at least partially encloses the package substrate.

9. The electronic device of claim 1, wherein the spacing distance between is controlled at least partially according to a die location in a given packaged electronic device design.

10. An electronic device, comprising:
a semiconductor die having: a semiconductor body; a metallization structure over the semiconductor body; and a conductive terminal, the metallization structure including a top level a top metal structure that extends in a plane of orthogonal first and second directions, the top metal structure electrically coupled to the conductive terminal, the conductive terminal extending over a portion of the top metal structure and away from the plane along a third direction that is orthogonal to the first and second directions, and the top metal structure overlaps all lateral edges of the conductive terminal by a non-zero overlap distance; and
a package structure that at least partially encloses the semiconductor die.

11. The electronic device of claim 10, wherein:
the top metal structure has a thickness along the third direction; and
the overlap distance is greater than the thickness.

12. The electronic device of claim 10, wherein:
the conductive terminal is soldered to a conductive feature of a package substrate; and
the package structure at least partially encloses the package substrate.

13. A system, comprising:
a circuit board; and
an electronic device having a semiconductor die and a package structure, the semiconductor die having: a semiconductor body; a metallization structure over the semiconductor body; and a conductive terminal, the metallization structure including a top level having neighboring first and second top metal structures that extend in a plane of orthogonal first and second directions, the first top metal structure electrically coupled to the conductive terminal, the conductive terminal extending over a portion of the first top metal structure and away from the plane along a third direction that is orthogonal to the first and second directions, and the first top metal structure spaced apart from the second top metal structure in the plane by a spacing distance of 60 μm or more, and the package structure at least partially encloses the semiconductor die.

14. The system of claim 13, wherein the second top metal structure is the nearest top metal structure to the first top metal structure in the top level of the metallization structure.

15. The system of claim 13, wherein the spacing distance is 80 μm or more.

16. The system of claim 15, wherein:
the first top metal structure overlaps all lateral edges of the conductive terminal by a non-zero overlap distance.

17. The system of claim 13, wherein:
the conductive terminal is soldered to a conductive feature of a package substrate; and
the package structure at least partially encloses the package substrate.

18. A method of fabricating an electronic device, the method comprising:
forming a metallization structure over a semiconductor body, including forming a top level having neighboring first and second top metal structures in a plane of orthogonal first and second directions, the first top metal structure spaced apart from the second top metal structure in the plane by a spacing distance of 60 μm or more;
forming a protective overcoat layer over the metallization structure; and
forming a conductive terminal electrically coupled to the conductive terminal and extending through the protective overcoat layer over a portion of the first top metal structure and away from the plane along a third direction that is orthogonal to the first and second directions.

19. The method of claim 18, wherein the spacing distance is 80 μm or more.

20. The method of claim 18, wherein the first top metal structure overlaps all lateral edges of the conductive terminal by a non-zero overlap distance.

21. The method of claim 20, wherein:
the first top metal structure has a thickness along the third direction; and
the overlap distance is greater than the thickness.
